(19) United States
(12) Patent Application Publication
(10) Pub. No.: US 2008/0061383 A1
(43) Pub. Date: Mar. 13, 2008

(54) Semiconductor device having fin field effect transistor and manufacturing method thereof

(75) Inventor: Keizo Kawakita, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 11/896,719

(22) Filed: Sep. 5, 2007

(30) Foreign Application Priority Data
Sep. 7, 2006 (JP) 2006-242902

(51) Int. Cl. H01L 29/78; H01L 21/336

(52) U.S. Cl. 257/410; 438/287; 257/E21.409; 257/E29.255

(57) ABSTRACT

A semiconductor device in which the concentration of the electric field at upper end portions (corner portions) of a fin-shaped active region is eased and deterioration of the threshold voltage of the FinFET is suppressed, and that has a high current driving performance, and a manufacturing method thereof are provided. The semiconductor device comprising: a fin-shaped active region having a top surface and side surfaces; a gate electrode covering the active region; a first gate insulating film formed between the top surface of the active region and the gate electrode; and a second gate insulating film formed between the side surfaces of the active region and the gate electrode, wherein the first gate insulating film is thicker than the second gate insulating film, and a dielectric constant of the first gate insulating film is higher than that of the second gate insulating film.

### TECHNICAL FIELD

The present invention relates to a semiconductor device and a manufacturing method thereof, and particularly to a semiconductor device that includes a fin field effect transistor and a manufacturing method thereof.

### BACKGROUND OF THE INVENTION

In recent years, following downsizing of a memory cell in a DRAM (Dynamic Random Access Memory), a gate length of a memory cell transistor is inevitably reduced. However, if the gate length is smaller, then the short channel effect of the transistor disadvantageously becomes more conspicuous, and sub-threshold current is disadvantageously increased. Furthermore, if substrate concentration is increased to suppress the short channel effect and the increase of the sub-threshold current, junction leakage increases. Due to this, the DRAM is confronted with a serious problem of deterioration in refresh characteristics.

As a technique for avoiding the above-stated problem, attention is paid to a fin field effect transistor (hereinafter, “FinFET”) structured so that channel regions are formed to be thin each in the form of a fin in a perpendicular direction to a semiconductor substrate and so that gate electrodes are arranged around the channel regions (see Japanese Patent Application Laid-open No. 2005-317978 and Japanese Patent Application Laid-open No. 2002-118255). The FinFET is expected to be able to realize acceleration of operating rate, increase in ON-current, reduction in power consumption and the like, as compared with a planer transistor.

FIG. 29A is a cross-section of a channel region of a conventional FinFET in a direction perpendicular to an extending direction of a gate electrode. FIG. 29B is an enlarged view of corner portions 205 shown in FIG. 29A.

As shown in FIG. 29A, a trench for STI (Shallow Trench Isolation) is formed on a semiconductor substrate 200. This trench is filled with an element isolation insulating film up to a predetermined height from the bottom, thereby forming an STI region 201. A part of the semiconductor substrate 200 that is positioned above the STI region 201 is a fin-shaped active region 202. On a top surface and side surfaces of the fin-shaped active region 202, a gate insulating film 203 is formed. A gate electrode 204 is formed on the gate insulating film 203 so as to cover the channel region of the active region 202.

In such a FinFET, when a voltage is applied to the gate electrode 204, a channel is formed not only on the top surface of the active region 202, but also on the side surfaces, thereby improving the operation speed and the on-current.

However, in the conventional FinFET, electric field concentration occurs at the corner portions (upper end portions) 205 of the active region 202, and there has been a problem that the threshold voltage of the FinFET decreases.

Specifically, as shown in FIG. 29B showing a partial enlarged view of the upper end portion 205 of the active region 202, an electric field that is indicated by lines of electric force expressed by arrows is applied to the gate insulating film 203 (only one of the corner portions 205 is shown in FIG. 29B). Therefore, at the corner portion of the active region 202 having a substantially right angle, the electric field concentrates excessively (density of the lines of electric force becomes high). As a result, the withstand voltage of the transistor is lowered, thereby decreasing the threshold voltage.

Countermeasures to this problem include a method in which concentration of impurity in the semiconductor substrate 200 is increased. However, if the concentration of impurity is increased, the electric field of the source and drain regions becomes strong. This leads to deterioration of the refresh characteristic particularly in the DRAM.

As another countermeasure, it can be considered to perform a rounding process by oxidization on the upper end portions 205 before forming the gate insulating film 203. However, this makes the process redundant and causes a problem that a control of the shape is difficult.

Further as another countermeasure, it can be considered to form the gate insulating film 203 thick in whole. However, this causes a problem that a current driving performance is lowered.

Furthermore, because of the concentration of the electric field at the upper end portions 205 of the active region 202, the gate leakage current flows. As a result, a loss of power consumption is caused. For this problem also, a countermeasure in which the gate insulating film 203 is formed thick entirely. However, the same problem as the above is caused.

### SUMMARY OF THE INVENTION

Therefore, an object of the present invention is to provide a semiconductor device in which the concentration of the electric field at upper end portions (corner portions) of a fin-shaped active region is eased and deterioration of the threshold voltage of the FinFET is suppressed, and that has a high current driving performance, and a manufacturing method thereof.

According to the present invention, there is provided a semiconductor device comprising: a fin-shaped active region having a top surface and side surfaces; a gate electrode covering the active region; a first gate insulating film formed between the top surface of the active region and the gate electrode; and a second gate insulating film formed between the side surfaces of the active region and the gate electrode, wherein the first gate insulating film is thicker than the second gate insulating film, and a dielectric constant of the first gate insulating film is higher than that of the second gate insulating film.

According to the present invention, there is provided a method of manufacturing a semiconductor device comprising: a first step for forming a first gate insulating film on a top surface of a fin-shaped active region; and a second step for forming a second gate insulating film on each of side surfaces of the fin-shaped active region separately from the first step, wherein film thickness of the first gate insulating film is thicker than film thickness of the second gate insulating film, and the first gate insulating film is formed with a material having higher dielectric constant than the second gate insulating film.

As described above, according to the present invention, a first gate insulating film that is formed on the top surface of a fin-shaped active region is formed thicker than a second gate insulating film that is formed on each of side surfaces of the active region, and a material having higher dielectric constant than the second gate insulating film is used as a material of the first gate insulating film. Therefore, the concentration of the electric field at the upper end portions (corner portions) of the fin-shaped active region can be eased without lowering the on-current. Thus, deterioration of the threshold voltage of a FinFET can be suppressed.

### BRIEF DESCRIPTION OF THE DRAWINGS

The above and other objects, features and advantages of this invention will become more apparent by reference to the following detailed description of the invention taken in conjunction with the accompanying drawings, wherein:

FIGS. 1A and 1B are diagrams for explaining a configuration of a FinFET 1 according to a preferred embodiment of the present invention; where FIG. 1A is a cross-section of a channel region of the FinFET in a direction perpendicular to an extending direction of a gate electrode, and FIG. 1B is a partial enlarged view of 15 shown in FIG. 1A;

FIGS. 2A and 2B are diagrams for explaining a configuration of a FinFET 2 according to a preferred embodiment of the present invention; where FIG. 2A is a cross-section of a channel region of the FinFET in a direction perpendicular to an extending direction of a gate electrode, and FIG. 2B is a partial enlarged view of 25 shown in FIG. 2A;

FIGS. 3A and 3B are diagrams for explaining a configuration of a FinFET 3 according to a preferred embodiment of the present invention; where FIG. 3A is a cross-section of a channel region of the FinFET in a direction perpendicular to an extending direction of a gate electrode, and FIG. 3B is a partial enlarged view of 35 shown in FIG. 3A;

FIG. 4 is a plan view of the FinFET formed in the present embodiment;

FIGS. 5A, 5B and 5C are cross-sections showing a process (formation of a gate insulating film 20t to formation of a silicon nitride film 102) in a manufacturing method of a semiconductor device according to a preferred embodiment of the present invention;

FIGS. 6A, 6B and 6C are cross-sections showing a process (formation of a trench 103t) in the manufacturing method of the semiconductor device according to the preferred embodiment of the present invention;

FIGS. 7A, 7B and 7C are cross-sections showing a process (formation of a silicon oxide film 103h and ion implantation) in the manufacturing method of the semiconductor device according to the preferred embodiment of the present invention;

FIGS. 8A, 8B and 8C are cross-sections showing a process (formation of a silicon oxide film 103d) in the manufacturing method of the semiconductor device according to the preferred embodiment of the present invention;

FIGS. 9A, 9B and 9C are cross-sections showing a process (polishing of the silicon oxide film 103d) in the manufacturing method of the semiconductor device according to the preferred embodiment of the present invention;

FIGS. 10A, 10B and 10C are cross-sections showing a process (formation of a photoresist 104) in the manufacturing method of the semiconductor device according to the preferred embodiment of the present invention;

FIGS. 11A, 11B and 11C are cross-sections showing a process (formation of an STI region 103i) in the manufacturing method of the semiconductor device according to the preferred embodiment of the present invention;

FIGS. 12A, 12B and 12C are cross-sections showing a process (ion implantation) in the manufacturing method of the semiconductor device according to the preferred embodiment of the present invention;

FIGS. 13A, 13B and 13C are cross-sections showing a process (removal of the photoresist 104) in the manufacturing method of the semiconductor device according to the preferred embodiment of the present invention;

FIGS. 14A, 14B and 14C are cross-sections showing a process (formation of a gate insulating film 20s) in the manufacturing method of the semiconductor device according to the preferred embodiment of the present invention;

FIGS. 15A, 15B and 15C are cross-sections showing a process (formation of a polysilicon film 106) in the manufacturing method of the semiconductor device according to the preferred embodiment of the present invention;

FIGS. 16A, 16B and 16C are cross-sections showing a process (polishing of the polysilicon film 106) in the manufacturing method of the semiconductor device according to the preferred embodiment of the present invention;

FIGS. 17A, 17B and 17C are cross-sections showing a process (removal of the silicon nitride film 102) in the manufacturing method of the semiconductor device according to the preferred embodiment of the present invention;

FIGS. 18A, 18B and 18C are cross-sections showing a process (formation of a polysilicon film 106t, W/WN film 107 and silicon nitride film 108) in the manufacturing method of the semiconductor device according to the preferred embodiment of the present invention;

FIGS. 19A, 19B and 19C are cross-sections showing a process (formation of a photoresist 109) in the manufacturing method of the semiconductor device according to the preferred embodiment of the present invention;

FIGS. 20A, 20B and 20C are cross-sections showing a process (formation of gate electrodes 110) in the manufacturing method of the semiconductor device according to the preferred embodiment of the present invention;

FIGS. 21A, 21B and 21C are cross-sections showing a process (formation of source/drain regions 111) in the manufacturing method of the semiconductor device according to the preferred embodiment of the present invention;

FIGS. 22A, 22B and 22C are cross-sections showing a process (formation of a silicon oxide film 112 in a manufacturing method of a semiconductor device according to another preferred embodiment of the present invention;

FIGS. 23A, 23B and 23C are cross-sections showing a process (formation of a photoresist 113) in the manufacturing method of the semiconductor device according to another preferred embodiment of the present invention;

FIGS. 24A, 24B and 24C are cross-sections showing a process (patterning of the silicon oxide film 112 and formation of an STI region 103i) in the manufacturing method of the semiconductor device according to another preferred embodiment of the present invention;

FIGS. 25A, 25B and 25C are cross-sections showing a process (patterning of the silicon nitride film 102 and ion implantation) in the manufacturing method of the semiconductor device according to another preferred embodiment of the present invention;

FIGS. 26A, 26B and 26C are cross-sections showing a process (removal of the photoresist 113 and formation of a gate insulating film 20s) in the manufacturing method of the semiconductor device according to another preferred embodiment of the present invention;

FIGS. 27A, 27B and 27C are cross-sections showing a process (formation of a polysilicon film 114) in the manufacturing method of the semiconductor device according to another preferred embodiment of the present invention;

FIGS. 28A, 28B and 28C are cross-sections showing a process (formation of gate electrodes 115) in the manufacturing method of the semiconductor device according to another preferred embodiment of the present invention; and

FIGS. 29A and 29B are diagrams for explaining a conventional FinFET; where FIG. 29A is a cross-section of a channel region of the FinFET in a direction perpendicular to an extending direction of a gate electrode, and FIG. 29B is a partial enlarged view of 205 shown in FIG. 29A.

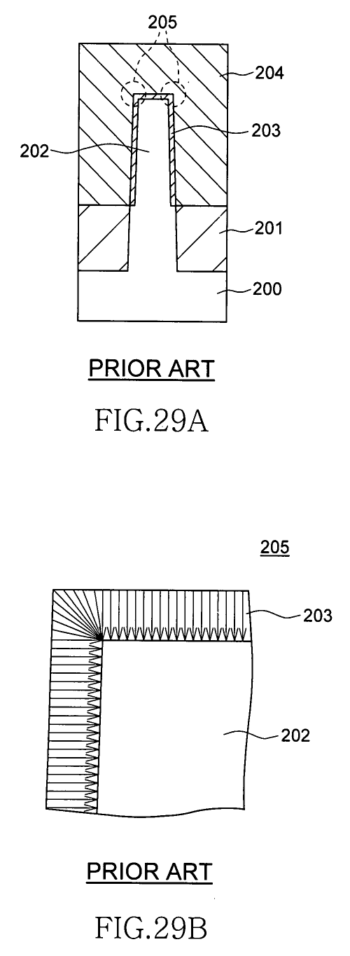

### DETAILED DESCRIPTION OF THE EMBODIMENTS

Preferred embodiments of the present invention will be explained below with reference to the accompanying drawings.

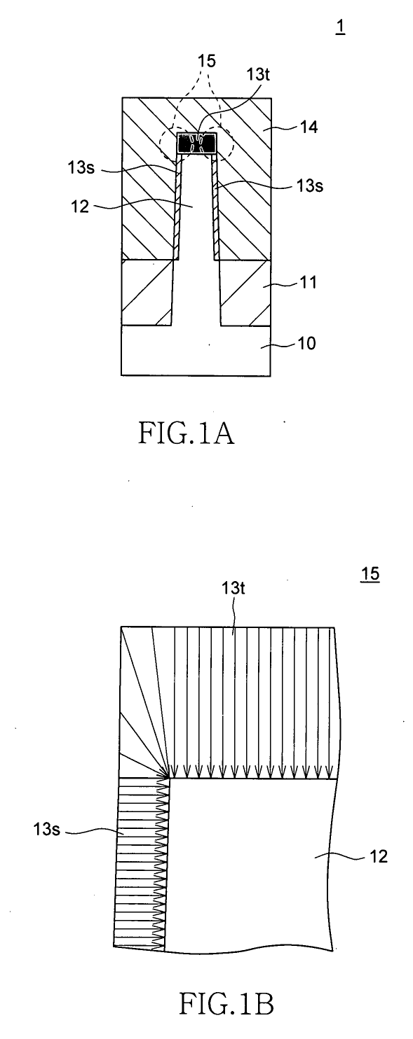

First, configurations of FinFETs 1, 2, and 3 according to preferred embodiments of the present invention are explained. FIGS. 1A, 2A, and 3A show cross-sections of a channel region of the FinFET in a direction perpendicular to an extending direction of a gate electrode, and FIGS. 1B, 2B, and 3B show partial enlarged views (each shows only one of the portions) of corner portions 15, 25, and 35 shown in FIGS. 1A, 2A, and 3A, respectively.

Since the FinFETs 1, 2, and 3 shown in FIGS. 1A, 2A, and 3A are common in configuration except for a gate insulating film, the configuration of common parts is explained first.

As shown in FIGS. 1A, 2A, and 3A, a trench for STI is formed on a semiconductor substrate 10, and the trench is filled with an element isolation insulating film up to a predetermined height from the bottom, thereby forming an STI region 11. A portion of the semiconductor substrate 10 positioned above the STI region 11 is a fin-shaped active region 12. On a top surface and side surfaces of the fin-shaped active region 12, a gate electrode 14 is formed through each gate insulating film, so as to cover a channel region of the active region 12.

Next, a configuration of the gate insulating film of each of the FinFETs 1, 2, and 3 is explained in detail below.

In the FinFET 1 shown in FIG. 1A, a gate insulation film 13t on the top surface of the active region 12 is formed thicker than gate insulating films 13s on the side surfaces thereof, and is formed with a material having higher dielectric constant than the gate insulating films 13s. Specifically, for example, the gate insulating film 13t on the top surface is formed with Hafnia (HfO₂) and the gate insulating films 13s on the side surfaces is formed with a silicon oxide film. The relative dielectric constant of Hafnia is approximately 25, and the relative dielectric constant of the silicon oxide film is approximately 4. Since the relative dielectric constant of Hafnia is about six times as high as that of the silicon oxide film, the thickness of the gate insulating film 13t on the top surface can be six times as thick as that of the gate insulating films 13s on the side surfaces.

In such a configuration, the electric field that is indicated by lines of electric force expressed by arrows is applied to the gate insulating film 13t and the gate insulating films 13s, as shown in FIG. 1B. Since the dielectric constant of the gate insulating film 13t is approximately six times as high as that of the gate insulating films 13s, even if the gate insulating film 13t is six times as thick as the gate insulating film 13s, strength (density of lines of electric force) of the electric field applied to the gate insulating film 13t and strength of the electric filed applied to the gate insulating films 13s become substantially equal. Therefore, under the gate insulating film 13t on the top surface of the active region 12, a channel equivalent to a channel formed under the gate insulating films 13s on the side surfaces of the active region 12 is formed. As described above, according to the FinFET 1, equivalent channels are formed on the top surface and the side surfaces of the active region 12, thereby preventing deterioration of the current driving performance. Furthermore, since the gate insulating film 13t is formed thick, it is possible to suppress the concentration of the electric field in the upper end of the active region 12.

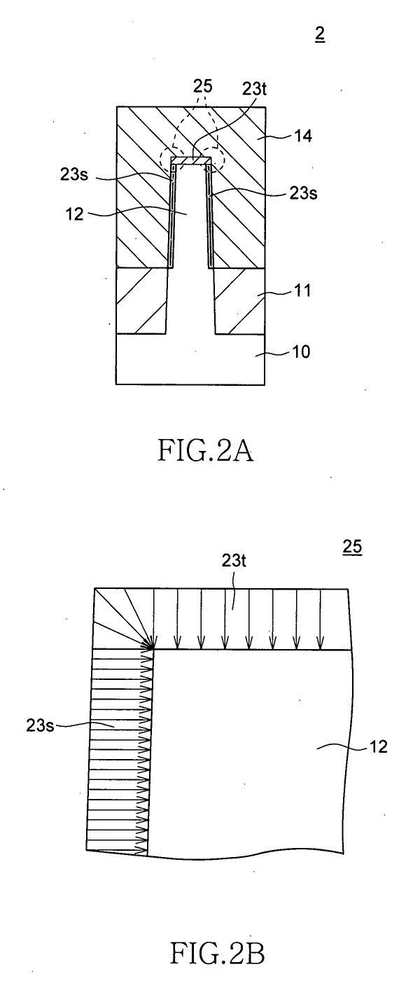

In the FinFET 2 shown in FIG. 2A, a gate insulating film 23t on a top surface of the active region 12 and gate insulating films 23s on side surfaces thereof are formed in substantially the same thickness, and the gate insulating films 23s are formed with a material having higher dielectric constant than the gate insulating film 23t. Specifically, for example, the gate insulating film 23t on the top surface of the active region 12 is formed with silicon oxide film, and the gate insulating films 23s on the side surfaces are formed with Hafnia (HfO₂). Moreover, in the FinFET 2, the thickness of the gate insulating films 23s and 23t is made thicker than the gate insulating films 13s shown in FIGS. 1A and 1B. In such a configuration, the electric field that is indicated by lines of electric force expressed by arrows is applied to the gate insulating film 23t and the gate insulating films 23s, as shown in FIG. 2B. In other words, the electric field in the gate insulating film 23t is weak (density of lines of electric force is low), and therefore, it is possible to ease the concentration of the electric field in the upper end portions of the active region 12. Furthermore, since the gate insulating films 23s has high dielectric constant, a sufficient channel is formed under the gate insulating films 23s, thereby obtaining high current driving performance.

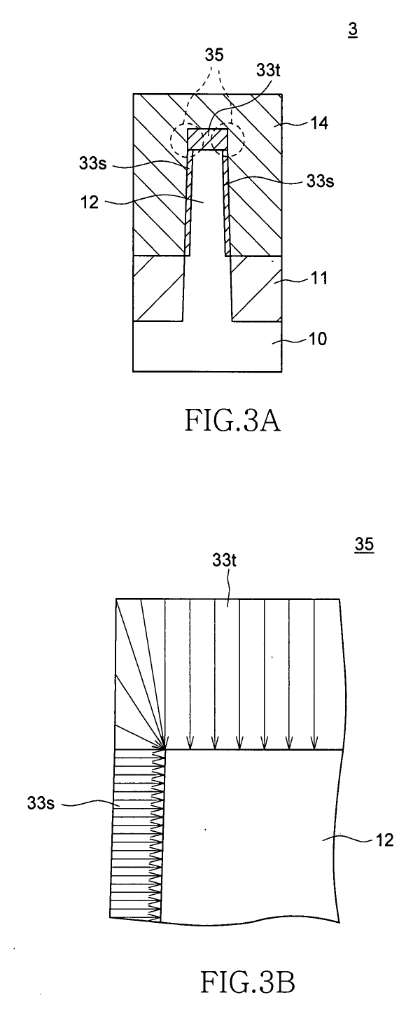

In the FinFET 3 shown in FIG. 3A, a gate insulating film 33t on a top surface of the active region 12 is formed thicker than gate insulating films 33s on side surfaces thereof. The gate insulating film 33t and the gate insulating films 33s are formed with the same material (for example, silicon oxide film).

The electric field that is indicated by lines of electric force expressed by arrows is applied to the gate insulating film 33t and the gate insulating films 33s, as shown in FIG. 3B. In other words, the electric field is strong (density of lines of electric force is high) in the thin gate insulating films 33s on the side surfaces of the active region 12. On the other hand, since the gate insulating film 33t on the top surface of the active region 12 is formed thick, the electric field is weak (density of lines of electric force is low). In such a configuration, the concentration of the electric field at the corners of the upper portion of the active region 12 can be eased (density of lines of electric force can be lowered) as shown in FIG. 3B. Therefore, it is possible to suppress decrease of the threshold voltage.

The channel formed under the gate insulating film 33t on the top surface of the active region 12 is weaker than the channel formed under the gate insulating films 33s on the side surfaces of the active region 12, and the current driving performance of the FinFET 1 is degraded a little. However, since most of the on-current flows near the side surfaces of the active region 12 in FinFETs, substantial degradation of the current driving performance does not occur. Therefore, according to the FinFET 3 shown in FIGS. 3A and 3B, it is possible to obtain a FinFET having a sufficiently high performance while easing the concentration of the electric field.

As described above, according to the present embodiments, by adjusting and selecting thickness and materials of gate insulating films, a FinFET having a necessary current driving performance and a desirable threshold voltage can be provided.

While in the above explanation, Hafnia (HfO₂) is used as a material having high dielectric constant that is used for the gate insulating films 13t and 23s, it is not limited thereto, and another high dielectric constant film such as hafnium silicate (HfSiO) and hafnium aluminate (HfAlO) can be used. Alternatively, a layered film composed of a silicon oxide film, a silicon nitride film, and a silicon oxide film, or the like can be used.

Moreover, while in the above explanation, a silicon oxide film is used as the gate insulating films 13s, 23t, and 33s as an example, a different insulating film can, of course, be used.

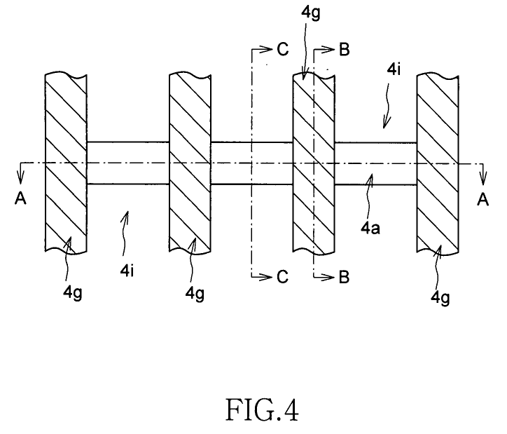

Next, with reference to FIGS. 4 and 5A to 21C, a manufacturing method of a FinFET according to a preferred embodiment of the present invention is explained in detail, taking a FinFET in which gate insulating films are configured as shown in FIGS. 1A and B, as an example.

FIG. 4 is a plan view of a FinFET formed in the present embodiment. As shown in FIG. 4, an STI region 4i is arranged so as to surround a fin-shaped active region 4a, and a plurality of gate electrodes 4g are formed in a direction substantially perpendicular to the active region 4a.

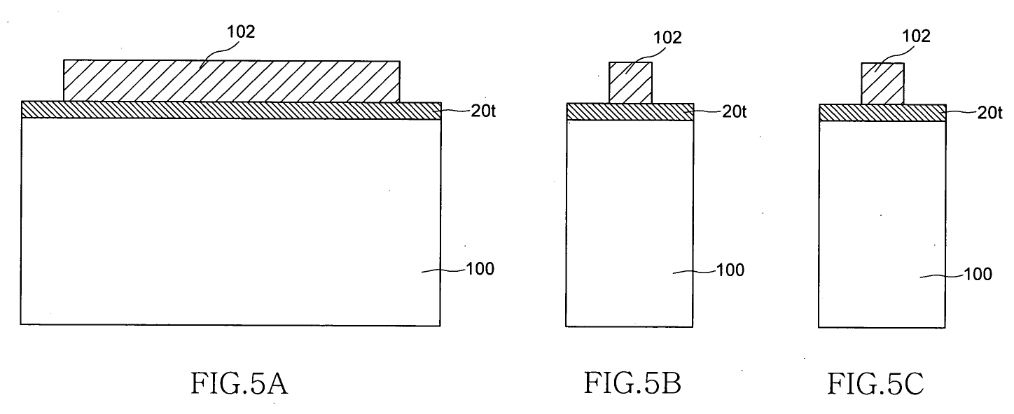

FIGS. 5A to 21C are cross-sections showing processes in the manufacturing method of a FinFET according to the present embodiment. FIGS. 5A to 21A, FIGS. 5B to 21B, and FIGS. 5C to 21C correspond to cross-sections taken along a line A-A, cross-sections taken along a line B-B, and cross-sections taken along a line C-C in FIG. 4, respectively.

As shown in FIGS. 5A, 5B and 5C, on an entire surface of a semiconductor substrate 100 on which a well structure (not shown) is formed by an ordinary process, a Hafnia (HfO₂) film is formed in the thickness of approximately 35 nm to 45 nm, and more preferably, in the thickness of approximately 40 nm. Thus, a first gate insulating film 20t formed with a Hafnia (HfO₂) film is formed.

Next, a silicon nitride film 102 in the thickness of approximately 120 nm is formed on the gate insulating film 20t. Thereafter, the silicon nitride film 102 is patterned in a form corresponding to the active region 4a shown in FIG. 4 by ordinary photolithography.

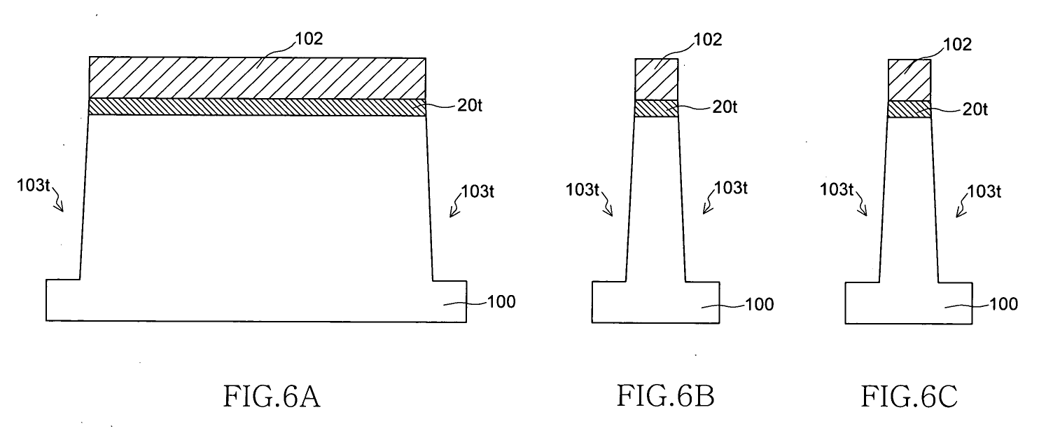

Subsequently, as shown in FIGS. 6A, 6B and 6C, the gate insulating film 20t and the semiconductor substrate 100 are etched, using the silicon nitride film 102 that has been patterned as a mask. Thus, a trench 103t for STI having a depth of approximately 200 nm is formed.

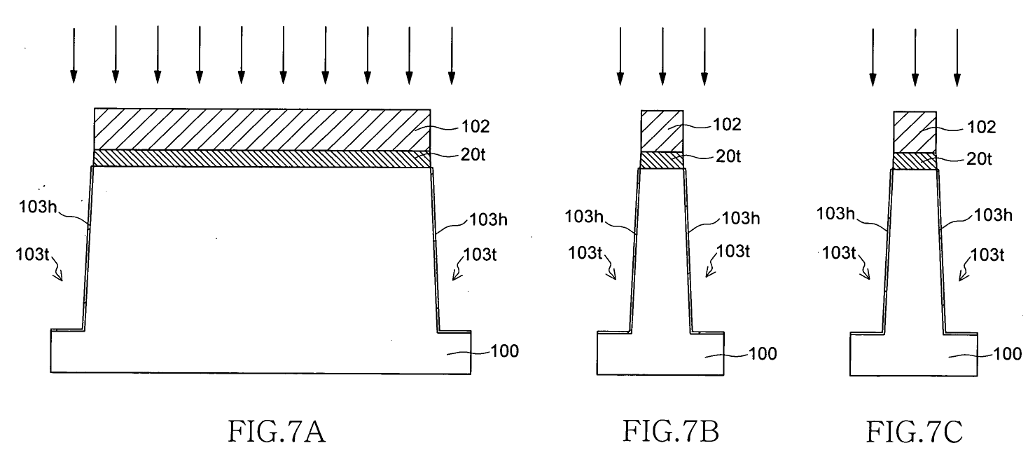

Next, as shown in FIGS. 7A, 7B and 7C, a silicon oxide film 103h having the thickness of approximately 7 nm to 13 nm is formed by thermally oxidizing a surface of the semiconductor substrate 100 that is exposed in the trench 103t. Thereafter, ion implantation expressed by arrows in FIGS. 7A, 7B and 7C is performed to obtain a necessary threshold voltage (Vth).

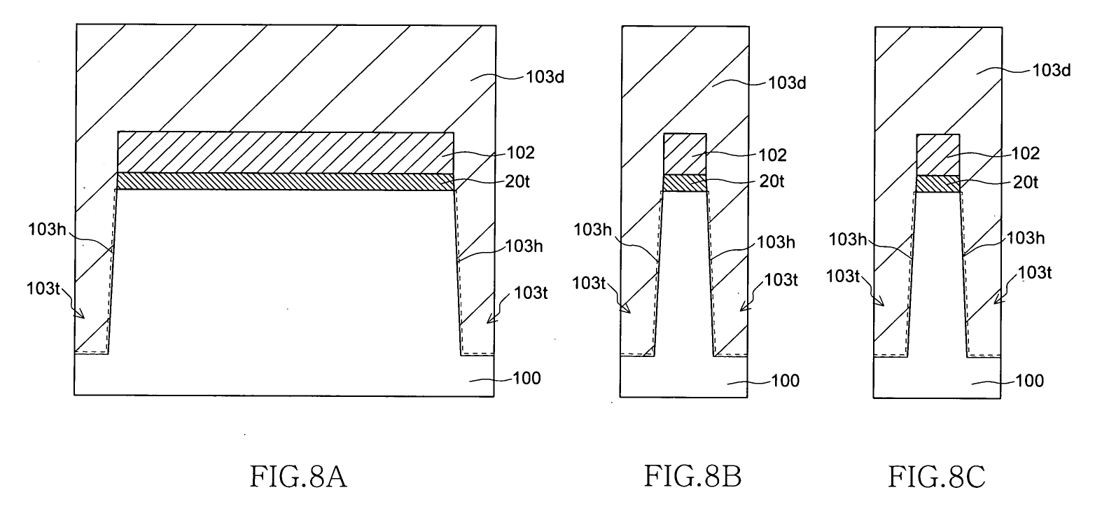

Thereafter, as shown in FIGS. 8A, 8B and 8C, a silicon oxide film 103d having the thickness of approximately 350 nm is formed on the entire surface so as to fill the trench 103t.

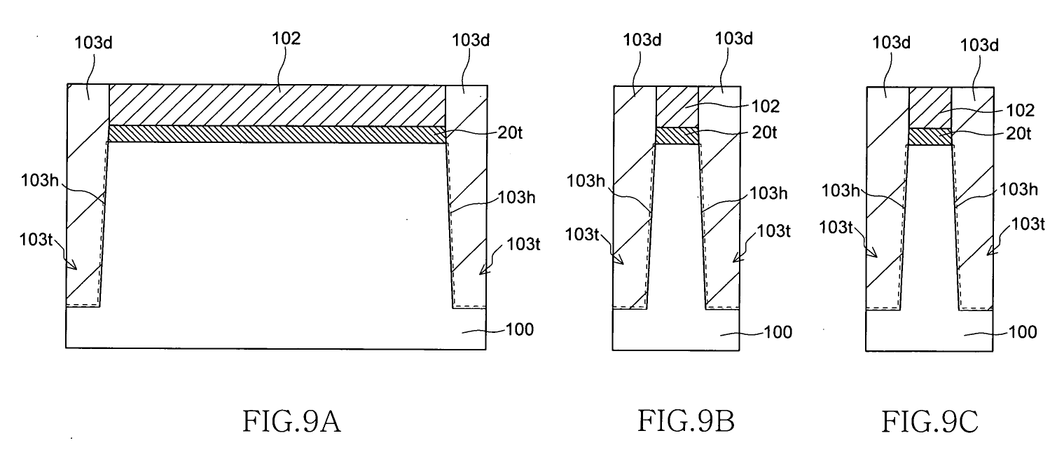

Subsequently, as shown in FIGS. 9A, 9B and 9C, the silicon oxide film 103d is polished by CMP (Chemical Mechanical Polishing), using the silicon nitride film 102 as a stopper.

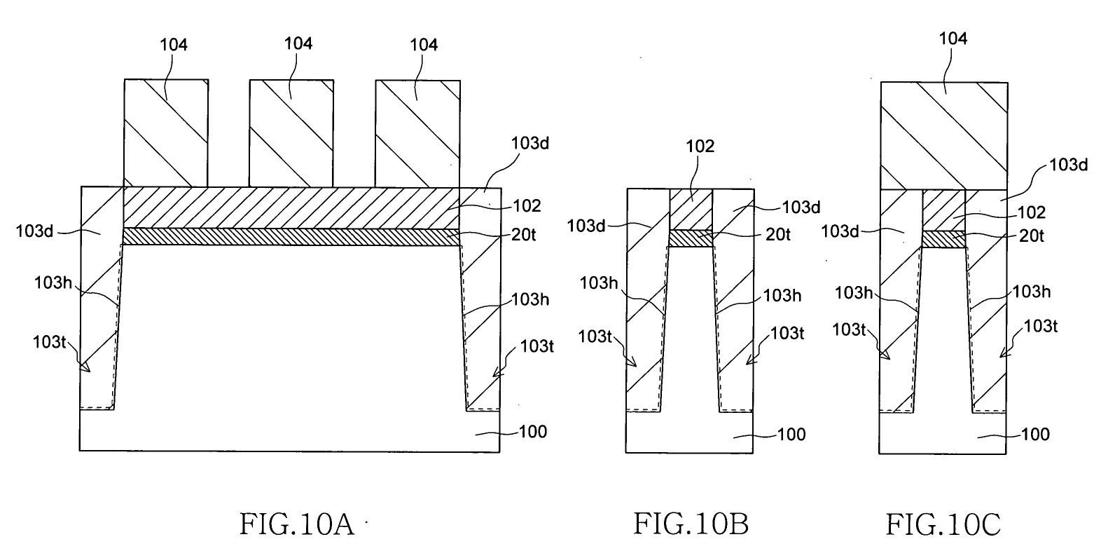

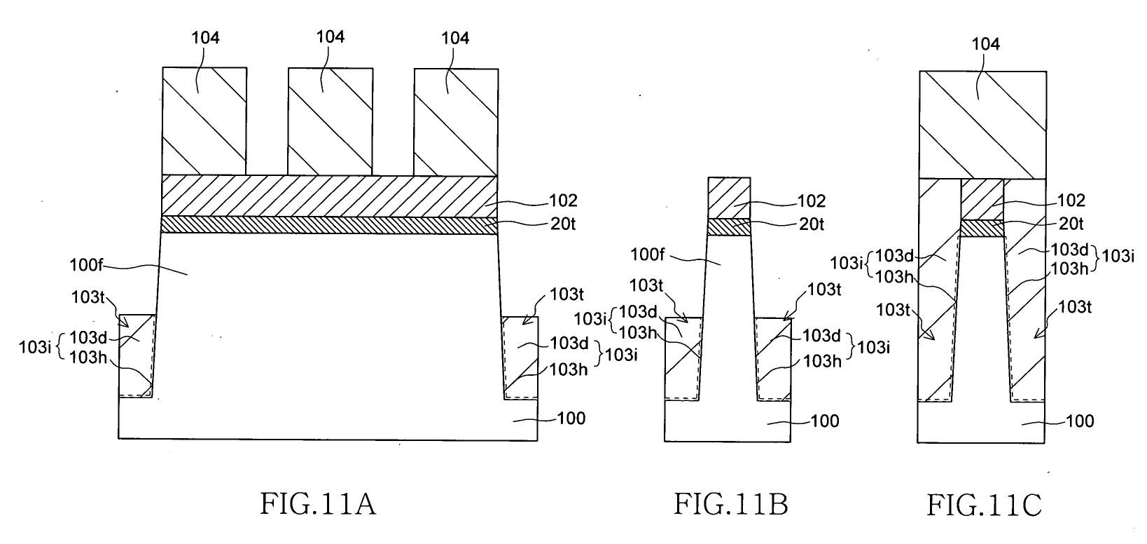

Next, as shown in FIGS. 10A, 10B and 10C, a photoresist 104 is formed, and a patterning is performed so as to expose a region (a portion of the gate electrode 4g shown in FIG. 4) in which a gate electrode is to be formed later. As shown in FIGS. 11A, 11B and 11C, the silicon oxide films 103d and 103h are then etched for about 100 nm using the silicon nitride film 102 and the photoresist 104 as a mask. Thus, an STI region 103i that is formed with the silicon oxide films 103d and 103h is formed, and a fin-shaped active region 100f that is a part of the semiconductor substrate 100 projecting from the upper surface of the STI region 103i is formed.

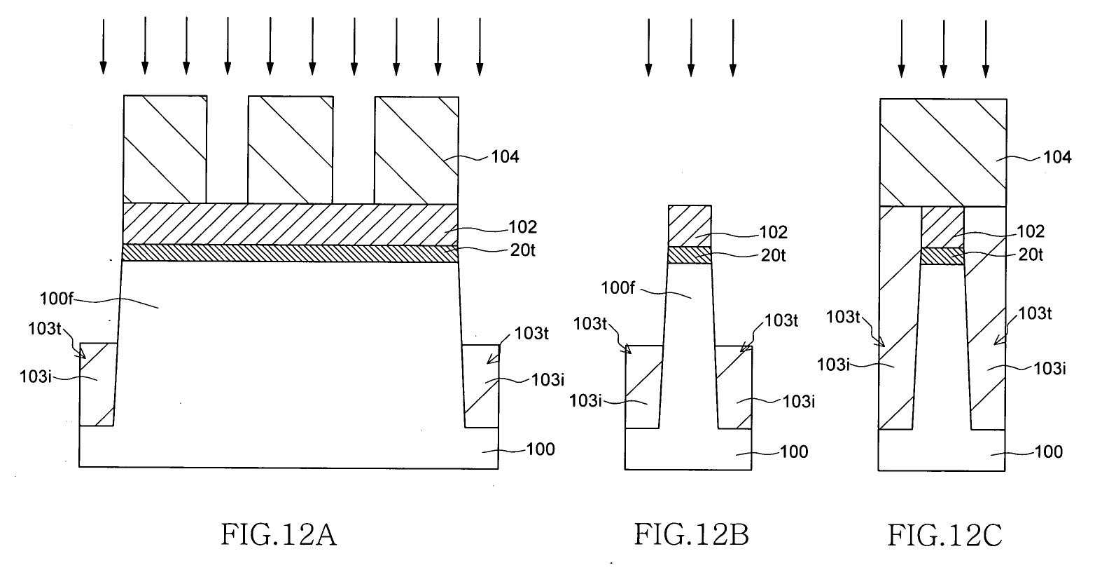

As shown in FIGS. 12A, 12B and 12C, ion implantation (channel doping) is performed on the surface of the active region 100f through the silicon nitride 102 and the gate insulating film 20t, using the photoresist 104 as a mask.

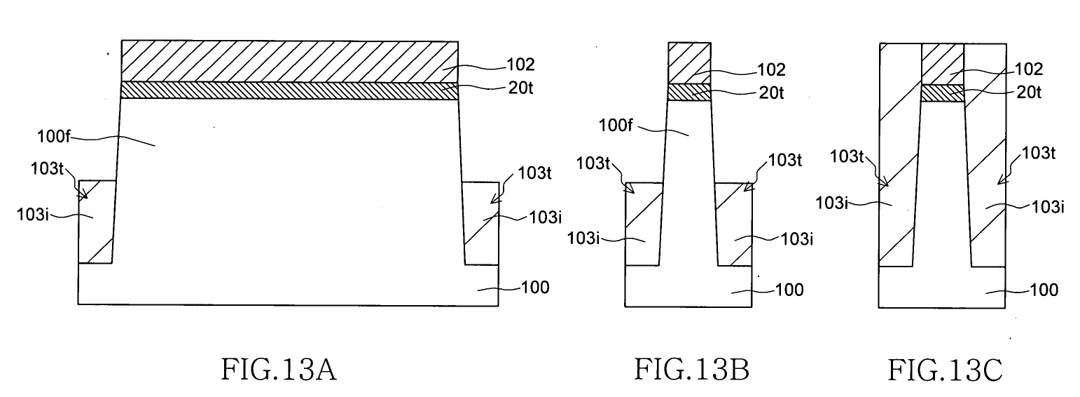

Thereafter, as shown in FIGS. 13A, 13B and 13C, the photoresist 104 is removed.

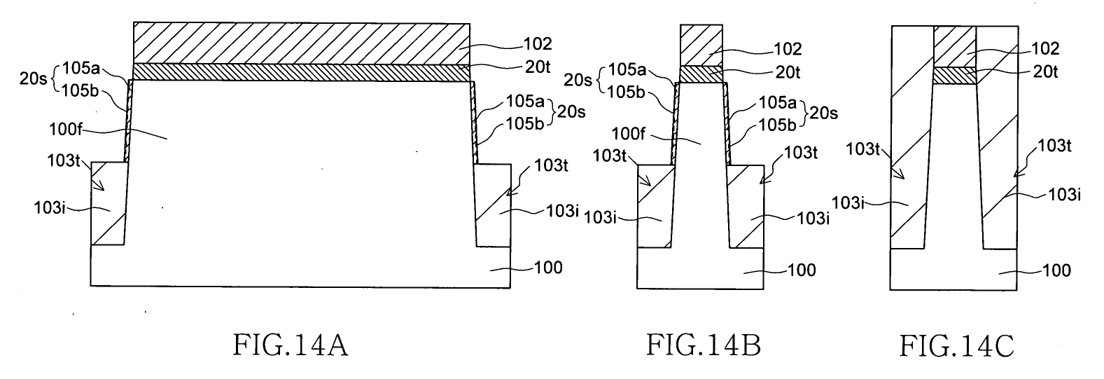

Next, as shown in FIGS. 14A, 14B and 14C, a silicon oxide film 105a having the thickness of approximately 6.5 nm is formed by thermal oxidization, on the side surfaces of the active region 100f that are exposed in the trench 103t. Furthermore, a silicon nitride film 105b is formed on the surface of the silicon oxide film 105a. Thus, a second gate insulating film 20s that is formed with the silicon oxide film 105a and the silicon nitride film 105b is formed on the side surfaces of the active region 100f.

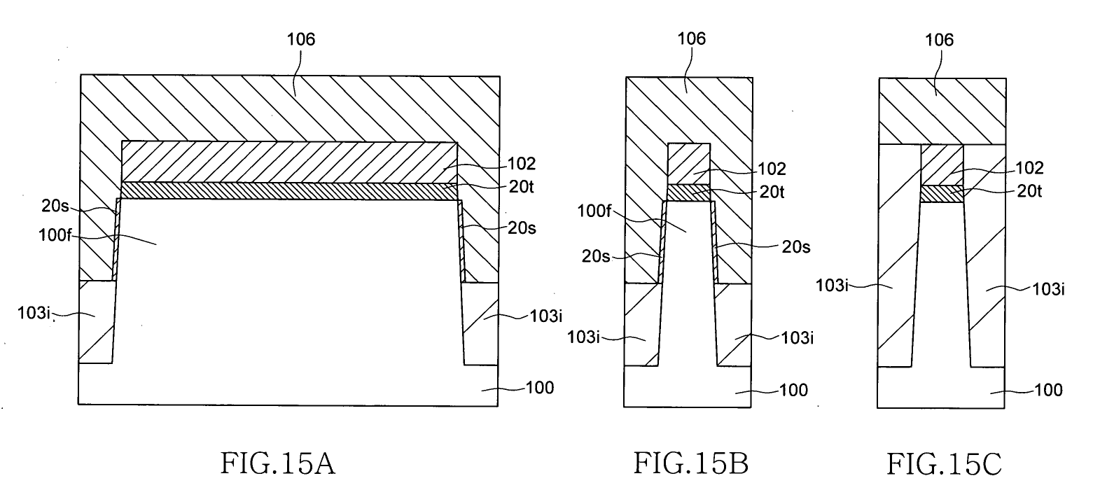

Next, as shown in FIGS. 15A, 15B and 15C, a polysilicon film 106 in which boron is doped is formed in the thickness of approximately 70 nm on the entire surface including on the gate insulating film 20s on the side surfaces on the active region 100f. The polysilicon film 106 can be formed such that the film is first formed without doping and boron is doped into the film by ion implantation in a later process.

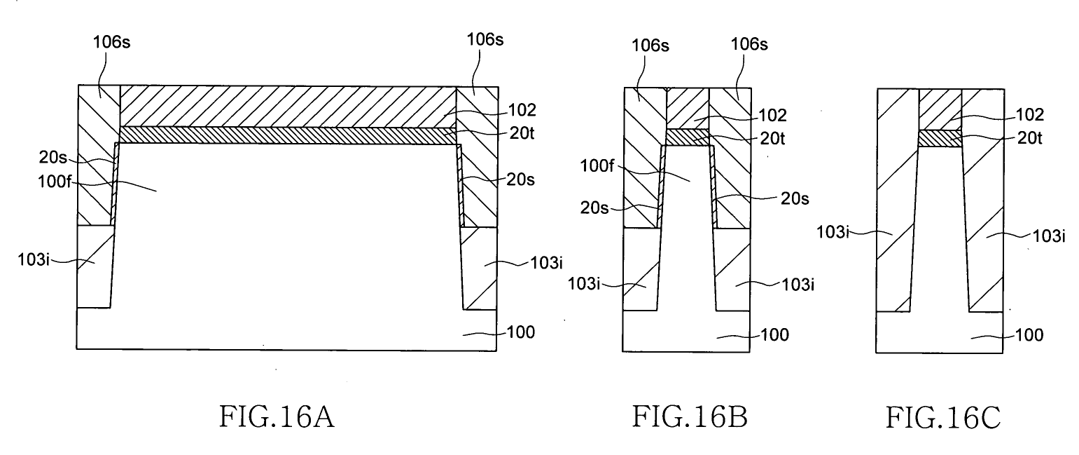

Subsequently, as shown in FIGS. 16A, 16B and 16C, an upper portion of the polysilicon film 106 is removed by performing CMP using the silicon nitride film 102 as a stopper. Thus, polysilicon films 106s constituting a part of the gate electrode is formed on the gate insulating films 20s on the side surfaces of the fin-shaped active region 100f.

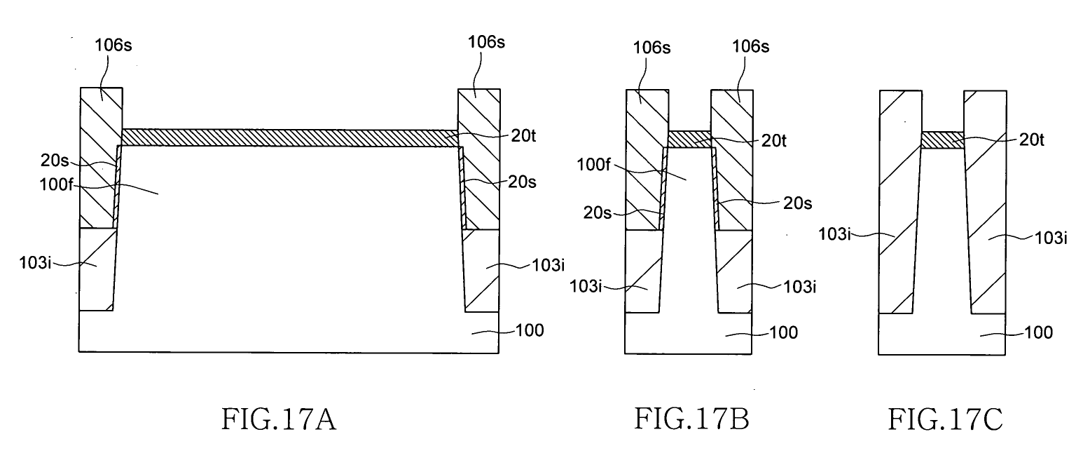

Thereafter, by selectively removing the silicon nitride film 102, a structure shown in FIGS. 17A, 17B and 17C is obtained.

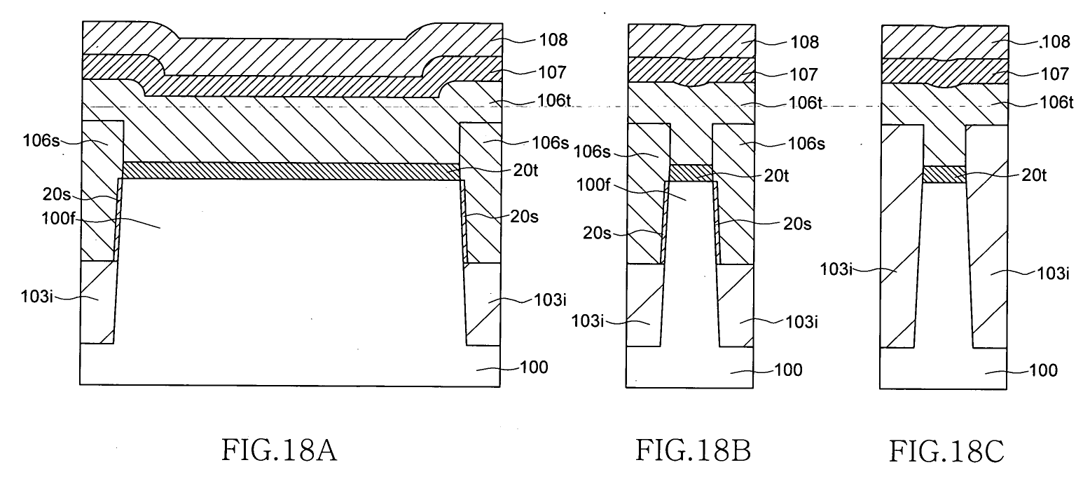

Next, as shown in FIGS. 18A, 18B and 18C, a polysilicon film 106t in which boron is doped is formed in the thickness of approximately 70 nm on the gate insulating film 20t on the top surface of the active region 100f. Similarly to the above, the polysilicon film 106t can be formed such that the film is first formed without doping and boron is doped into the film by ion implantation in a later process. When a transistor having a dual gate structure is formed, a P-type impurity can be doped in a region in which a P-type MOS transistor is to be formed, and an N-type impurity can be doped in a region in which an N-type MOS transistor is to be formed by ordinary lithography and ion implantation.

Next, as shown in FIGS. 18A, 18B and 18C, a layered film (W/WN film) 107 that is composed of a tungsten nitride film having the thickness of approximately 5 nm and a tungsten film having the thickness of approximately 50 nm is formed on the polysilicon film 106t. Subsequently, a silicon nitride film 108 having the thickness of approximately 100 nm is formed on the W/WN film 107.

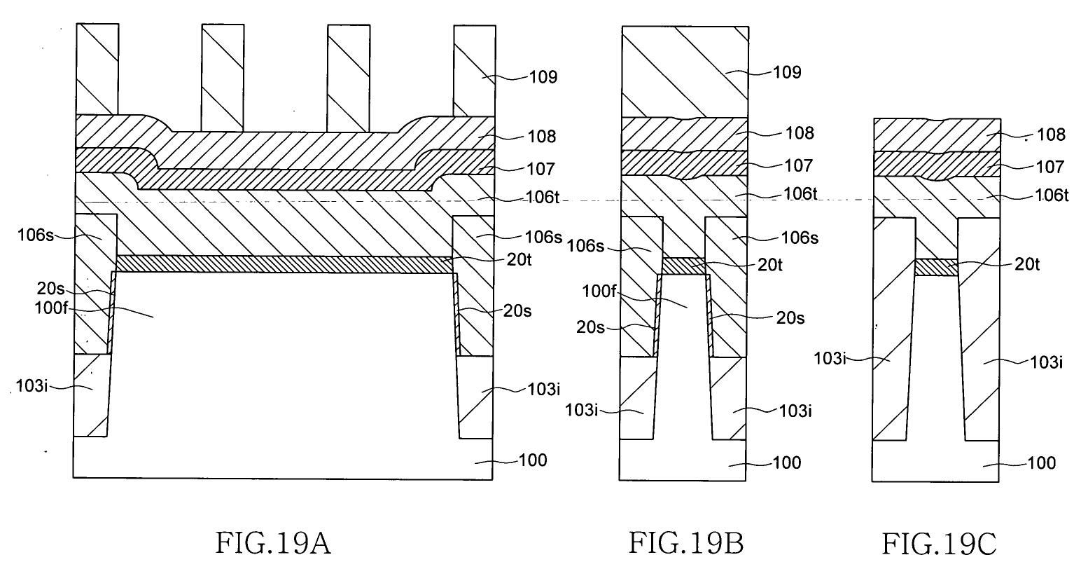

Next, as shown in FIGS. 19A, 19B and 19C, a photoresist 109 is formed on the silicon nitride film 108, and is patterned in a gate electrode form.

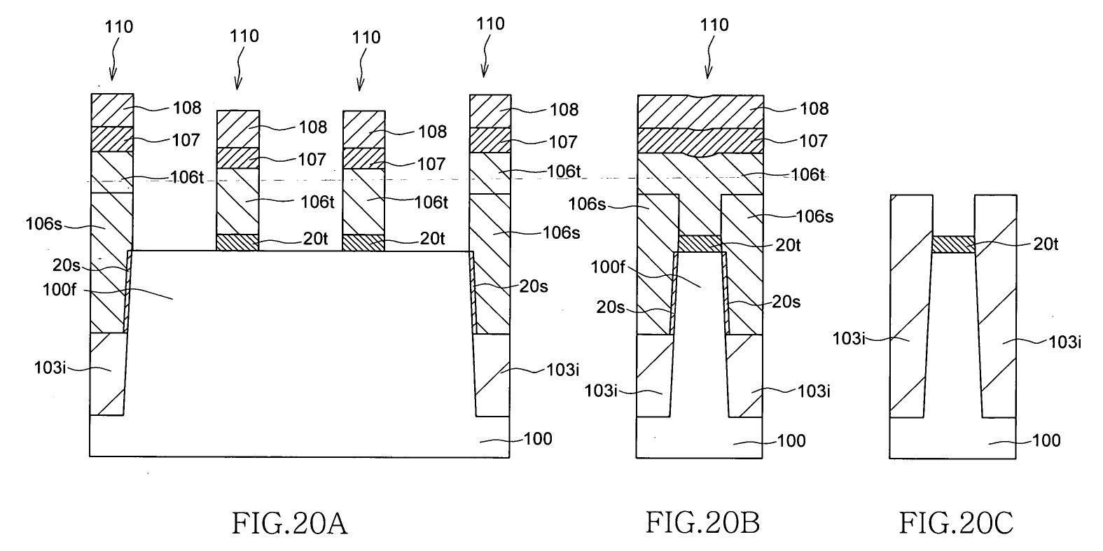

Subsequently, the silicon nitride film 108 is patterned using the photoresist 109 as a mask. Further, the W/WN film 107 and the polysilicon films 106t and 106s are patterned using the silicon nitride film 108 that has been patterned as a mask. Thus, gate electrodes 110 as shown in FIGS. 20A, 20B and 20C is completed.

As shown in FIG. 20B, the gate electrode 110 is formed so as to surround the side surfaces and the top surface of the fin-shaped active region 100f in the extending direction of the gate electrode 110. Specifically, the side surfaces of the active region 100f are covered with the polysilicon films 106s that is a part of the gate electrode 110 through the gate insulating film 20s, and the top surface of the active region 100f is covered with the polysilicon film 106t through the thick gate insulating film 20t.

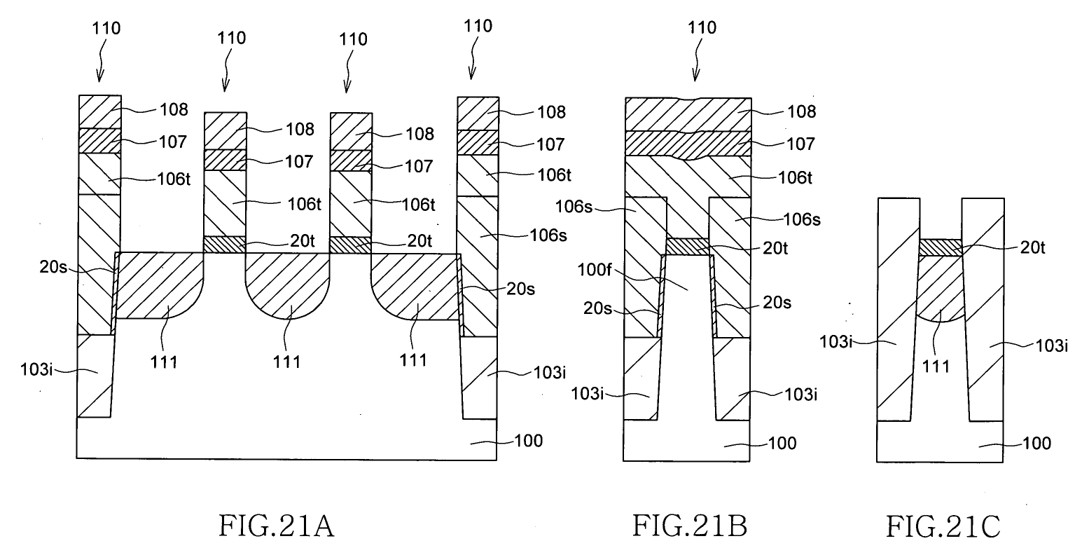

Next, as shown in FIGS. 21A, 20B and 20C, source/drain regions 111 are formed in the active region 100f by performing ion implantation using the gate electrodes 110 as a mask.

Thereafter, although not shown, necessary wiring and the like are formed, and a FinFET is completed.

As described above, according to the present embodiment, the gate insulating film 20t on the top surface of the fin-shaped active region can be formed thicker than (approximately six times as thick as) the gate insulating film 20s on the side surfaces thereof.

In the present embodiment, the silicon nitride film 102 that is formed on the gate insulating film 20t on the top surface of the active region 100f as a stopper in CMP is removed in the process shown in FIGS. 17A, 17B and 17C. However, this silicon nitride film 102 can be left without being removed, and can be used as a part of the gate insulating film 20t.

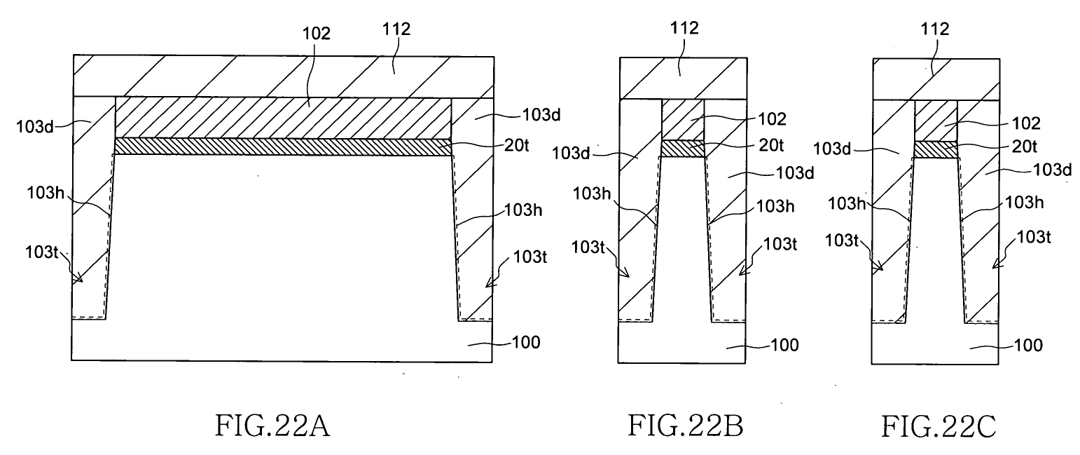

FIGS. 22A to 28C are cross-sections showing processes in a manufacturing method of a FinFET according to another embodiment. In the present embodiment, the gate electrode is formed by a damascene process. Since the processes shown in FIGS. 5A to 9C in the above embodiment are the same in the manufacturing method according to the present embodiment, the explanation thereof is omitted. Therefore, the processes shown in FIGS. 22A, 22B and 22C and after are explained as processes following the process shown in FIGS. 9A, 9B and 9C.

As shown in FIGS. 9A, 9B and 9C, after polishing the silicon oxide film 103d by CMP using the silicon nitride film 102 as a stopper, a silicon oxide film 112 is formed on the entire surface in the thickness of approximately 100 nm as shown in FIGS. 22A, 22B and 22C.

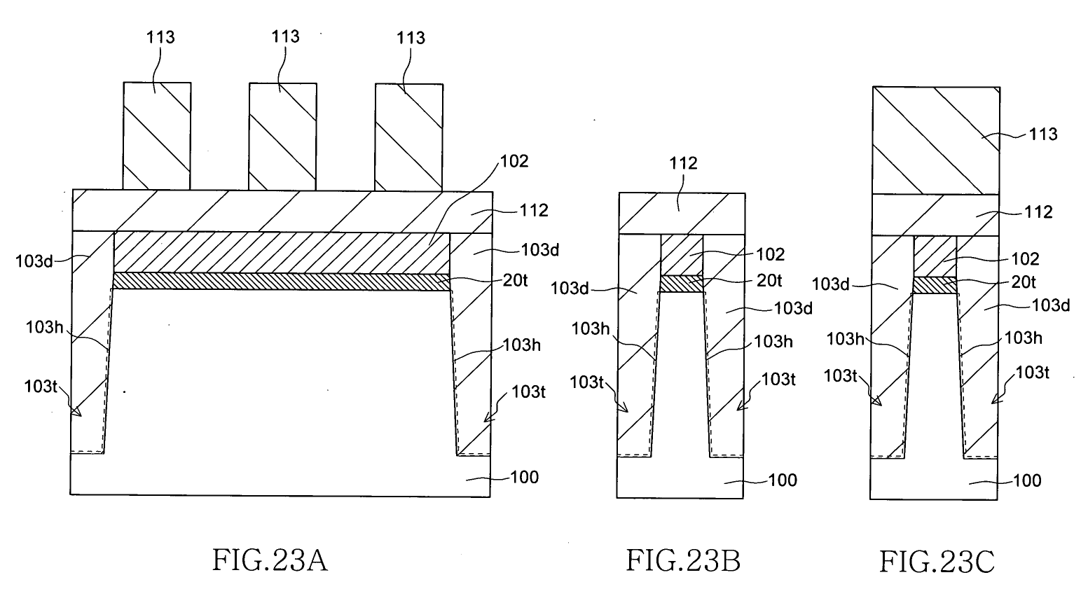

Next, as shown in FIGS. 23A, 23B and 23C, a photoresist 113 exposing a region to be a gate electrode (see FIG. 4) is formed on the silicon oxide film 112.

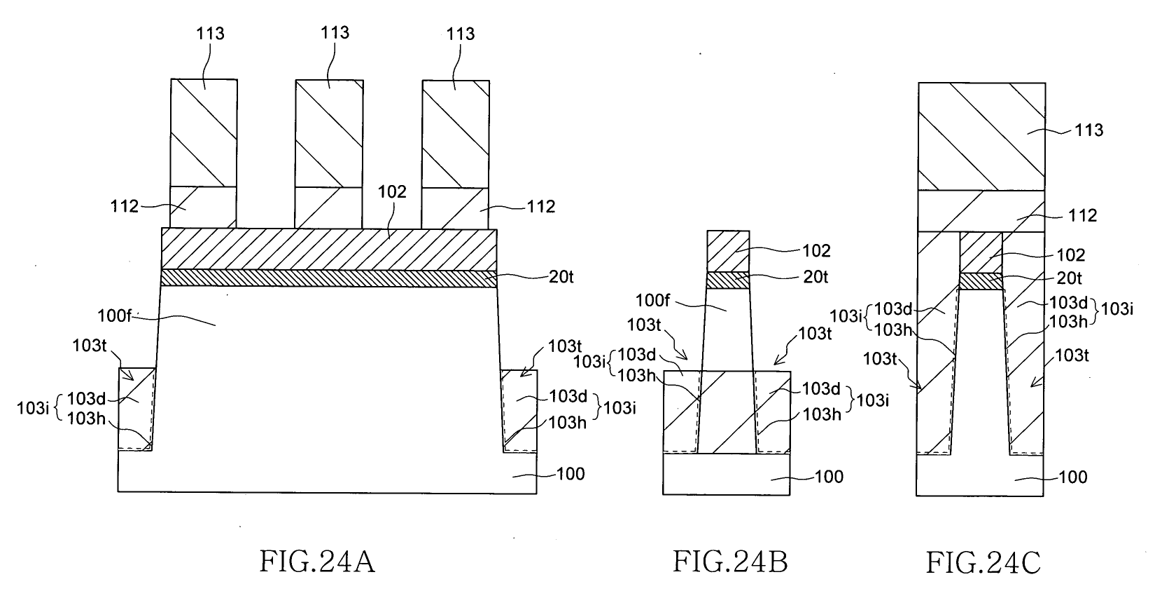

Next, as shown in FIGS. 24A, 24B and 24C, the silicon oxide film 112 is removed by etching, using the photoresist 113 as a mask. At this time, the silicon oxide films 103d and 103h are also etched about 100 nm. Thus, the STI region 103i composed of the silicon oxide films 103d and 103h is formed, and the fin-shaped active region 100f that is a part of the semiconductor substrate 100 projecting from the upper surface of the STI region 103i is formed.

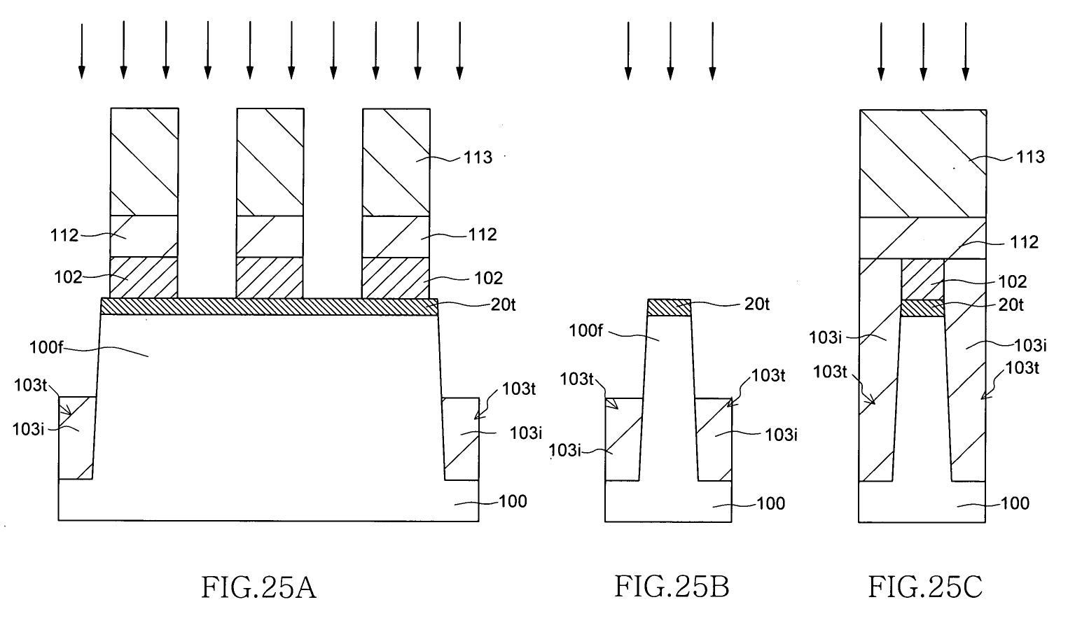

Subsequently, as shown in FIGS. 25A, 25B and 25C, the silicon nitride film 102 is removed by etching, using the photoresist 113 and the silicon oxide film 112 as a mask. At this time, the etching should be performed so as not to remove the gate insulating film 20t.

Next, ion implantation (channel doping) is performed on the surface of the active region 100f using the photoresist 113 as a mask.

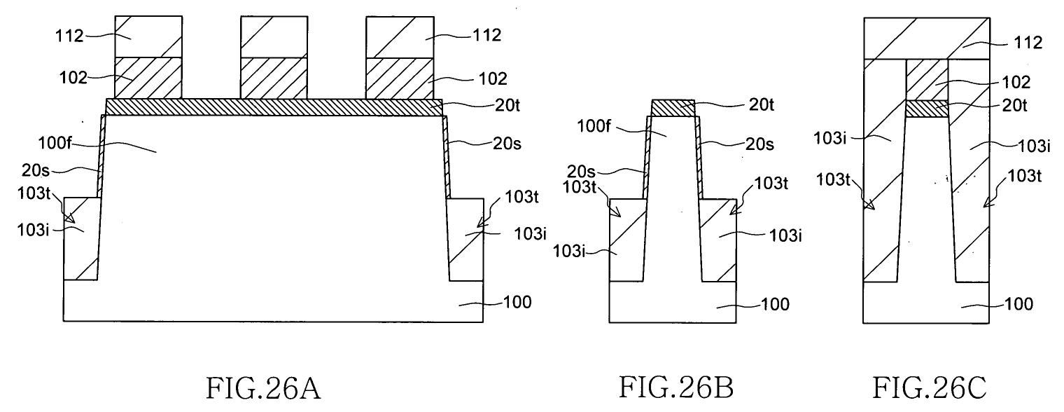

Subsequently, as shown in FIGS. 26A, 26B and 26C, after the photoresist 113 is removed, similarly to the above embodiment, silicon oxide films having the thickness of approximately 6.5 nm is formed by thermal oxidization on the side surfaces of the active region 100f that are exposed in the trench 103t. Further, a silicon nitride film is formed on the silicon oxide film. Thus, second gate insulating films 20s is formed on the side surfaces of the active region 100f.

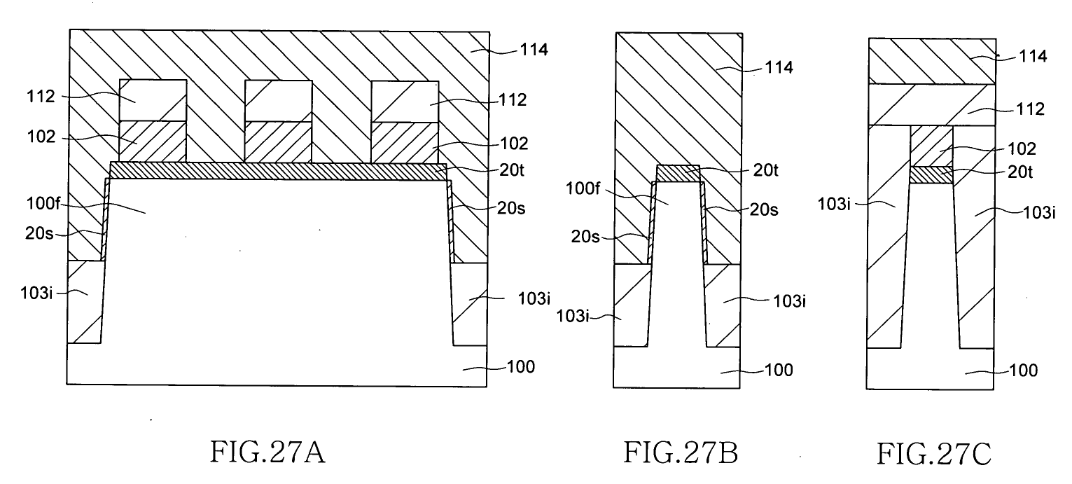

Next, as shown in FIGS. 27A, 27B and 27C, a polysilicon film 114 in which boron is doped is formed in the thickness of approximately 100 nm on the entire surface. The polysilicon film 114 can be formed such that after the film is first formed without doping, boron is doped into the film by ion implantation.

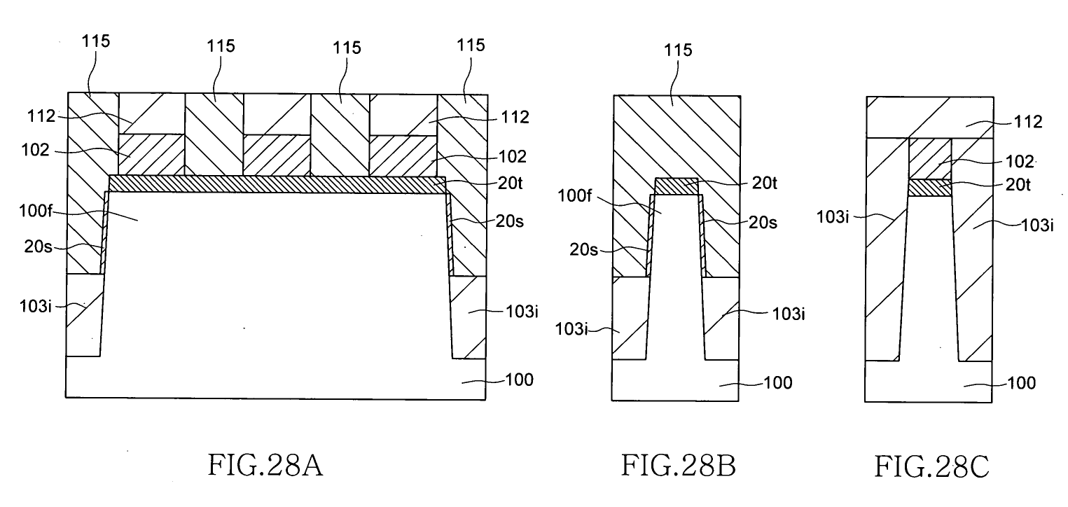

Next, as shown in FIGS. 28A, 28B and 28C, the polysilicon film 114 is polished by CMP until the surface of the silicon oxide film 112 is exposed. Thus, a plurality of gate electrodes 115 are formed in such a manner that the gate electrodes 115 are embedded between the layered films composed of the silicon nitride film 102 and the silicon oxide film 112.

Thereafter, although not shown, a diffusion layer, necessary wiring, and the like are formed, and a FinFET is completed.

As described above, according to the present embodiment also, the gate insulating film 20t on the top surface of a fin-shaped active region can be formed thicker than the gate insulating films 20s on the side surfaces thereof.

While a preferred embodiment of the present invention has been described hereinbefore, the present invention is not limited to the aforementioned embodiment and various modifications can be made without departing from the spirit of the present invention. It goes without saying that such modifications are included in the scope of the present invention.

For example, while in the embodiment of the above manufacturing method, an example in which a Hafnia (HfO₂) film is used as the gate insulating film 20t has been explained, a high dielectric constant film such as hafnium silicate (HfSiO) and hafnium aluminate (HfAlO) can be used as the gate insulating film 20t.

What is claimed is:

1. A semiconductor device comprising:
a fin-shaped active region having a top surface and side surfaces;
a gate electrode covering the active region;
a first gate insulating film formed between the top surface of the active region and the gate electrode; and
a second gate insulating film formed between the side surfaces of the active region and the gate electrode,
wherein the first gate insulating film is thicker than the second gate insulating film, and a dielectric constant: of the first gate insulating film is higher than that of the second gate insulating film.

2. The semiconductor device as claimed in claim 1, wherein the first gate insulating film includes at least one of Hafnia (HfO₂), hafnium silicate (HfSiO), and hafnium aluminate (HfAlO).

3. The semiconductor device as claimed in claim 1, wherein when a predetermined voltage is applied between the gate electrode and the active region, strength of an electric field applied to the first gate insulating film and strength of an electric field applied to the second gate insulating film are substantially equal.

4. The semiconductor device as claimed in claim 2, wherein when a predetermined voltage is applied between the gate electrode and the active region, strength of an electric field applied to the first gate insulating film and strength of an electric field applied to the second gate insulating film are substantially equal.

5. A manufacturing method of a semiconductor device, comprising:
a first step for forming a first gate insulating film on a top surface of a fin-shaped active region; and
a second step for forming a second gate insulating film on each of side surfaces of the fin-shaped active region separately from the first step, wherein
film thickness of the first gate insulating film is thicker than film thickness of the second gate insulating film, and
the first gate insulating film is formed with a material having higher dielectric constant than the second gate insulating film.

6. The manufacturing method of the semiconductor device as claimed in claim 5, wherein the first step includes:
a step for forming the first insulating film on an entire surface of a semiconductor substrate; and
a step for selectively etching the first gate insulating film and the semiconductor substrate so as to form the fin-shaped active region.

7. The manufacturing method of the semiconductor device as claimed in claim 5, further comprising:
a step for forming a part of a gate electrode on the second gate insulating film; and
a step for forming another part of the gate electrode on the first gate insulating film.

8. The manufacturing method of the semiconductor device as claimed in claim 6, further comprising:
a step for forming a part of a gate electrode on the second gate insulating film; and
a step for forming another part of the gate electrode on the first gate insulating film.

9. The manufacturing method of the semiconductor device as claimed in claim 5, further comprising a step for forming a gate electrode on the first gate insulating film and the second gate insulating film by a damascene process.

10. The manufacturing method of the semiconductor device as claimed in claim 6, further comprising a step for forming a gate electrode on the first gate insulating film and the second gate insulating film by a damascene process.

11. The manufacturing method of the semiconductor device as claimed in claim 7, further comprising a step for forming a gate electrode on the first gate insulating film and the second gate insulating film by a damascene process.

12. The manufacturing method of the semiconductor device as claimed in claim 8, further comprising a step for forming a gate electrode on the first gate insulating film and the second gate insulating film by a damascene process.
